(19) United States
(12) Patent Application Publication
(10) Pub. No.: US 2026/0098913 A1
(43) Pub. Date: Apr. 9, 2026

(54) SENSING ASSEMBLY, BATTERY ASSEMBLY INCLUDING THE SAME, AND METHOD FOR MANUFACTURING BATTERY ASSEMBLY

(71) Applicants: Hyundai Motor Company, Seoul (KR); Kia Corporation, Seoul (KR)

(72) Inventors: Kyung Mo KIM, Hwaseong-si (KR); Jong Gyu PARK, Hwaseong-si (KR); Gun Woo KO, Hwaseong-si (KR); Chan Sol KIM, Hwaseong-si (KR)

(21) Appl. No.: 19/230,506

(22) Filed: Jun. 6, 2025

(30) Foreign Application Priority Data
Oct. 8, 2024 (KR) 10-2024-0137126

(51) Int. Cl. G01R 31/396; G01R 31/3835; H01M 10/48

(52) U.S. Cl. CPC G01R 31/396; G01R 31/3835; H01M 10/482

(57) ABSTRACT

A battery assembly includes a battery cell stack including a plurality of battery cells that extend in a first direction and are arranged in a second direction transverse to the first direction, a side end plate disposed at one side of the battery cell stack in the second direction, and a sensing assembly that covers an area of a side surface of the battery cell stack in the first direction. The sensing assembly includes a sensing board and a sensing support frame supporting the sensing board.

### CROSS-REFERENCE TO RELATED APPLICATION

This application claims the benefit of priority to Korean Patent Application No. 10-2024-0137126, filed in the Korean Intellectual Property Office, on Oct. 8, 2024, the entire contents of which are incorporated herein by reference.

### TECHNICAL FIELD

The present disclosure relates to a sensing assembly, a battery assembly including the same, and a method for manufacturing the battery assembly.

### BACKGROUND

Electric vehicles are eco-friendly vehicles and can help mitigate environmental issues and depletion of petroleum resources. For example, the electric vehicles include plug-in hybrid electric vehicles (PHEVs), battery electric vehicle (BEVs), and fuel cell electric vehicles (FCEVs).

In some cases, an electric vehicle may include a battery housing that supports battery cells. An electric vehicle may use battery cells as a power source, and a battery assembly in the form of cell to pack (CTP) may be provided in an interior of the battery housing to increase the capacity of battery cells accommodated in a battery pack.

In some cases, the battery assembly may include a sensing assembly. The sensing assembly may be manually assembled to the battery pack.

### SUMMARY

The present disclosure describes a sensing assembly that can be automated in a manufacturing process, and a battery assembly including the same.

According to one aspect of the subject matter described in this application, a battery assembly includes a battery cell stack including a plurality of battery cells that extend in a first direction and are arranged in a second direction transverse to the first direction, a side end plate that is disposed at a side of the battery cell stack and faces the plurality of battery cells in the second direction, and a sensing assembly that covers an area of a side surface of the battery cell stack and faces the plurality of battery cells in the first direction, the sensing assembly including a sensing board and a sensing support frame that supports the sensing board. The sensing support frame includes a board support part that supports the sensing board and extends from the side of the battery cell stack in the second direction, a side support part that extends from an end of the board support part in the first direction and is supported by the side end plate, and a guide boss that protrudes from the end of the board support part in the second direction and is disposed on the side end plate.

Implementations according to this aspect can include one or more of the following features. For example, the guide boss can include a first stop area that extends in the first direction, and a second stop area that extends from the first stop area in a third direction transverse to the first and second directions. In some examples, the first stop area and the second stop area can contact the side end plate. In some examples, the side end plate can include a first contact surface that faces one side of the first stop area in the first direction and contacts one end of the first stop area, and a second contact surface that faces one side of the second stop area in the third direction and contacts one end of the second stop area.

In some implementations, the side end plate can define a recessed area between the first contact surface and the second contact surface, the recessed area being recessed in a direction away from the guide boss.

In some implementations, the sensing assembly further includes a busbar electrically connected to the plurality of battery cells, where the sensing support frame includes a plurality of busbar support parts that support the busbar and extend from the board support part in a third direction transverse to the first and second directions. The plurality of busbar support parts can be spaced apart from one another in the second direction to thereby define a plurality of tab slots that extend in the third direction. In some examples, each of the plurality of busbar support parts can include a protrusion that is disposed at an end of one of the busbar support parts in the third direction, that protrudes in the first direction, and that supports the busbar.

In some implementations, the side end plate can define a seating groove that is recessed in the second direction and receives the side support part. For examples, the seating groove can include a first seating area that extends in the first direction, a second seating area that extends from a first end of the first seating area in a third direction transverse to the first and second directions, a third seating area that extends from a second end of the first seating area in the third direction, and a fourth seating area that extends from the third seating area in the first direction.

In some examples, the side support part can include a first side area that extends in the first direction and is inserted into the first seating area, a second side area that extends from a first end of the first side area in the third direction and is inserted into the second seating area, a third side area that extends from a second end of the first side area in the third direction and is inserted into the third seating area, and a fourth side area that extends from the third side area in the first direction and is inserted into the fourth seating area.

In some implementations, the side end plate includes a rim cover that is disposed at one side of the first seating area in the third direction and supports the side support part. In some examples, the side end plate further includes a fixing jig that protrudes from the rim cover toward the first seating area and is disposed between the second seating area and the third seating area, the fixing jig being configured to fix the side support part. In some implementations, the seating groove extends in the first direction, and the side support part extends in the first direction and is inserted into the seating groove.

In some implementations, the sensing assembly further includes a wire electrically connected to the sensing board, where the wire is disposed at a surface of the side support part and extends along the side support part in the first direction.

According to another aspect, a sensing assembly includes a sensing board, a busbar, and a sensing support frame that supports the busbar and the sensing board. The sensing support frame includes a side support part that extends in a first direction, a board support part that extends from the side support part in a second direction transverse to the first direction, wherein the sensing board is attached to the board support part, and a plurality of busbar support parts to which the busbar is attached. The plurality of busbar support parts extend from the board support part in a third direction transverse to the first and second directions and are spaced apart from one another in the second direction.

Implementations according to this aspect can include one or more of the following features. For example, the sensing support frame further includes a guide boss that protrudes from the board support part to an outer side of the sensing support frame in the second direction, where the guide boss includes a first stop area that extends in the first direction, and a second stop area that extends from the first stop area in the third direction.

Implementations according to this aspect can include one or more of the following features. For example, the side support part includes a first side area that extends in the first direction, a second side area that extends from a first end of the first side area in the third direction, a third side area that extends from a second end of the first side area in the third direction, and a fourth side area that extends from the third side area in the first direction.

In some examples, each of the plurality of busbar support parts includes a protrusion that is disposed at an end of one the busbar support parts in the third direction, that protrudes in the first direction, and that supports the busbar. In some examples, the sensing assembly further includes a wire electrically connected to the sensing board, where the wire is disposed at a surface of the side support part and extends along the side support part in the first direction.

According to another aspect, a method for manufacturing a battery assembly includes stacking a plurality of battery cells that extend in a first direction, where the plurality of battery cells are stacked in a second direction transverse to the first direction, disposing a pair of side end plates at opposite sides of the plurality of battery cells, where the pair of side end plates face the plurality of battery cells in the second direction, and assembling a sensing assembly and the pair of side end plates in a third direction transverse to the first and second directions.

### BRIEF DESCRIPTION OF THE DRAWINGS

The above and other objects, features and advantages of the present disclosure will be more apparent from the following detailed description taken in conjunction with the accompanying drawings.

FIG. 1 is a perspective view illustrating an example of a battery pack.

FIG. 2 is an exploded perspective view of the battery pack.

FIG. 3 is a perspective view illustrating an example of a battery assembly.

FIG. 4 is an exploded perspective view of the battery assembly.

FIG. 5 is a perspective view illustrating an example of a sensing assembly.

FIG. 6 is a perspective view of the sensing assembly, when viewed from another angle.

FIG. 7 is an enlarged view of portion “A” illustrated in FIG. 3.

FIG. 8 is a perspective view illustrating an example of a sensing assembly.

FIG. 9 is a perspective view before the sensing assembly is mounted on a battery cell stack.

FIG. 10 is a view illustrating an example of a battery cell inserted into a tab slot of a busbar support part.

FIGS. 11 to 13 are views illustrating example processes of moving a sensing assembly to an opposite other side in a third direction and mounting it on a battery cell stack.

FIG. 14 is a flowchart illustrating an example of a method for manufacturing a battery assembly.

### DETAILED DESCRIPTION

Hereinafter, one or more implementations of the present disclosure will be described in detail with reference to the accompanying drawings. In adding reference numerals to the components of the drawings, it is noted that the same components are denoted by the same reference numerals even when they are drawn in different drawings. Furthermore, in describing the implementations of the present disclosure, when it is determined that a detailed description of related known configurations and functions can hinder understanding of the implementations of the present disclosure, a detailed description thereof will be omitted.

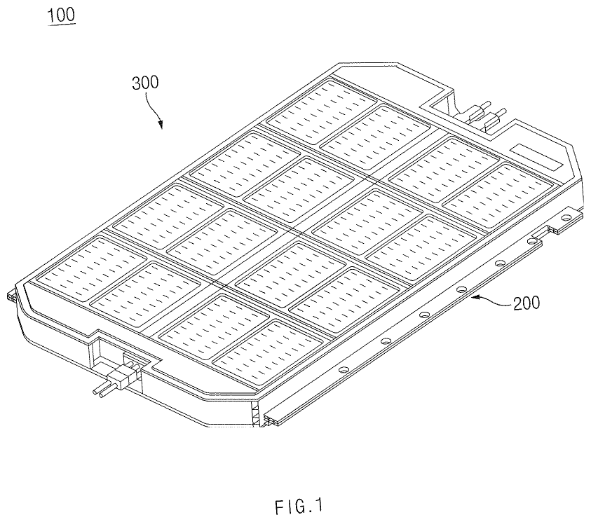

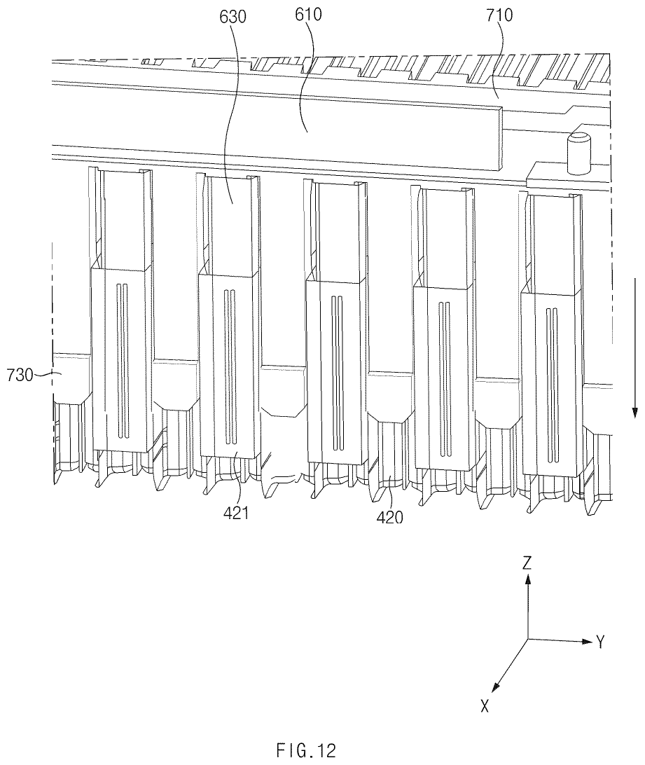

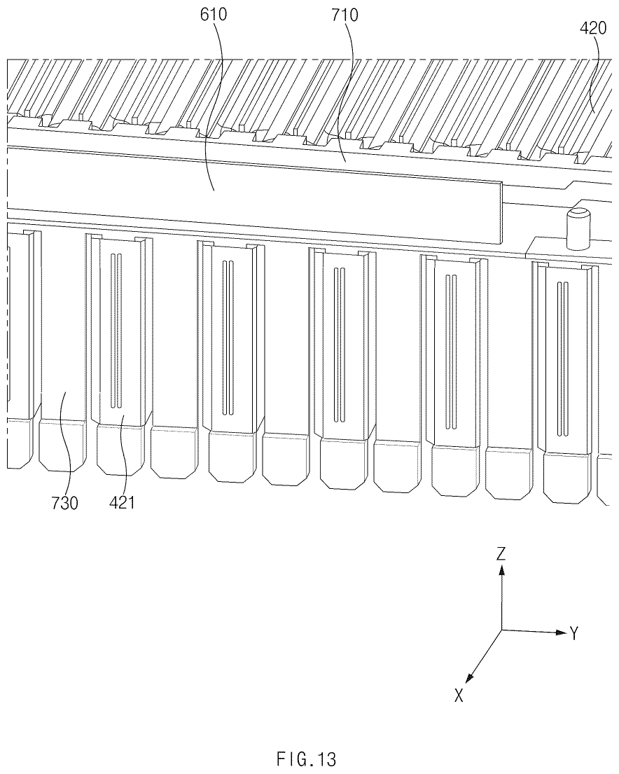

Hereinafter, one or more implementations of the present disclosure will be described in detail with reference to FIGS. 1 to 14.

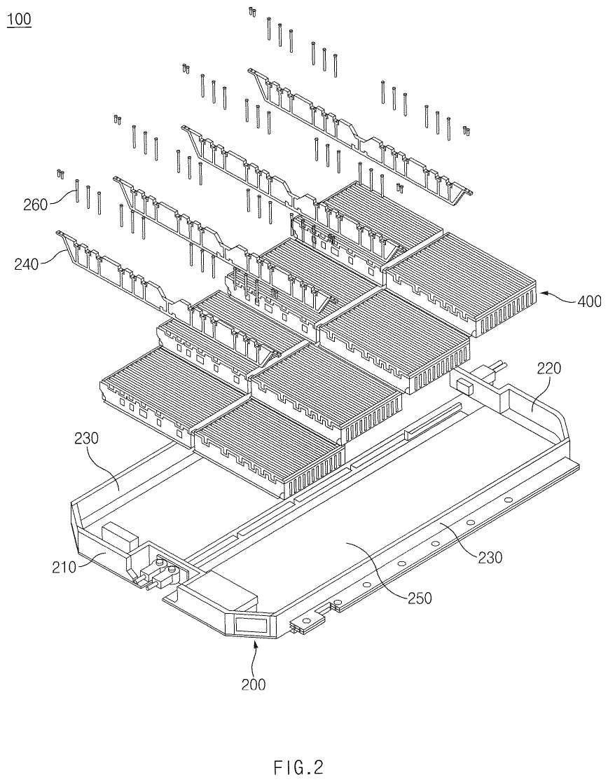

FIG. 1 is a perspective view of a battery pack. FIG. 2 is an exploded perspective view of a battery pack.

Referring to FIGS. 1 and 2, a battery pack 100 can include a battery housing 200, and a pack cover 300 that is coupled to the battery housing 200.

The battery housing 200 can define a space which accommodates a battery assembly 400. For example, the battery housing 200 can include a base plate 250, and a front member 210 and a rear member 220 that are coupled to the base plate 250.

In some implementations, the battery housing 200 can include a pair of side members 230 that connect the front member 210 and the rear member 220 and extend in parallel to each other. The front member 210, the rear member 220, and the pair of side members 230 can be coupled to the base plate 250 to define a space, in which the battery assembly 400 is accommodated.

The battery assembly 400 can be mounted on the battery housing 200 in the form of a cell to pack (CTP). In some cases, because the battery assembly 400 can be mounted on the battery housing 200 without the battery module housing, a battery capacity of the battery pack 100 can be relatively large.

For the battery assemblies 400 to be mounted in parallel to each other in an interior of the battery housing 200, the battery housing 200 can include a cross member 240 for guiding a position of the battery assembly 400. The cross member 240 can extend to connect a pair of side members 230 between the front member 210 and the rear member 220. The cross member 240 can be fixed to the base plate 250 by a fixing member 260.

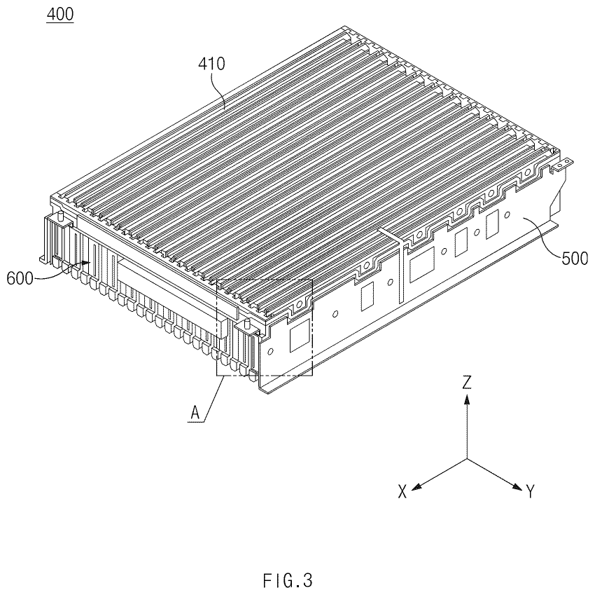

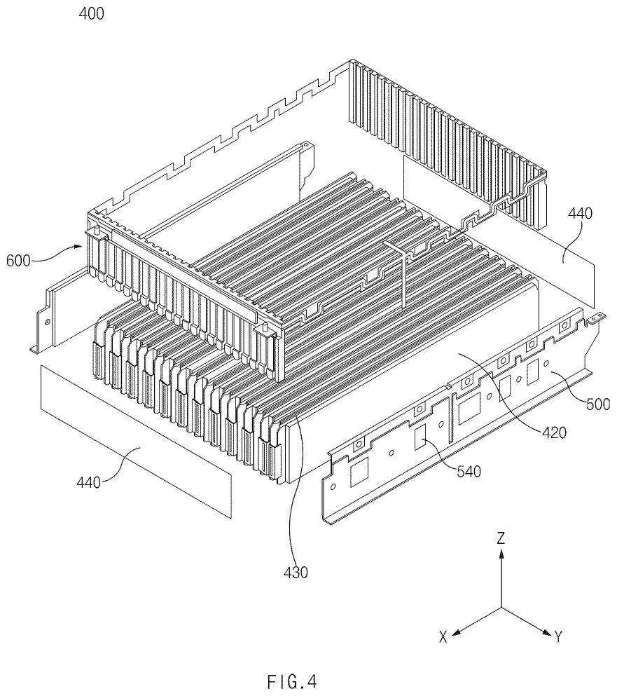

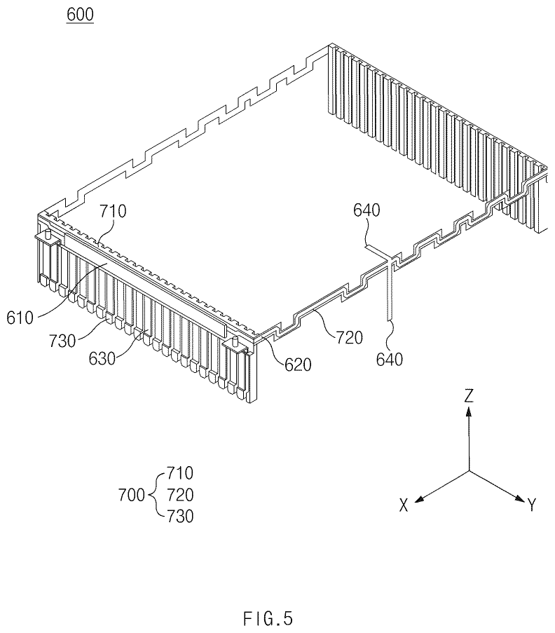

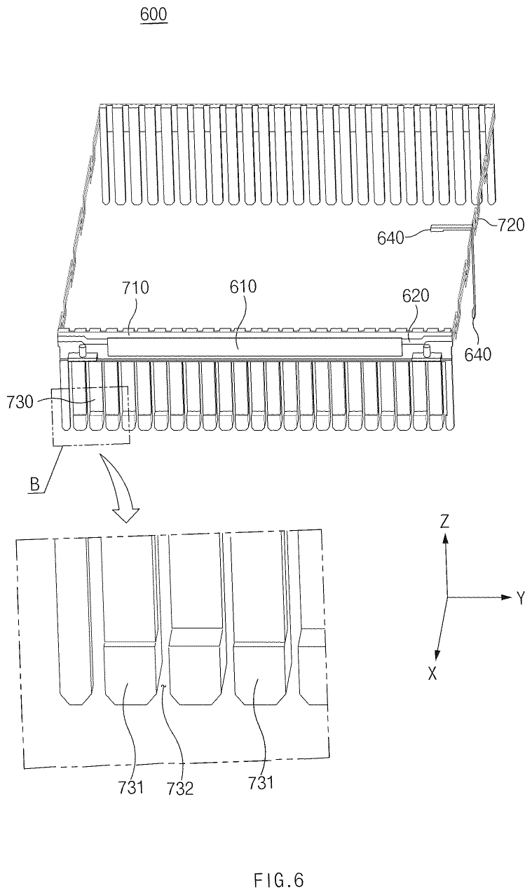

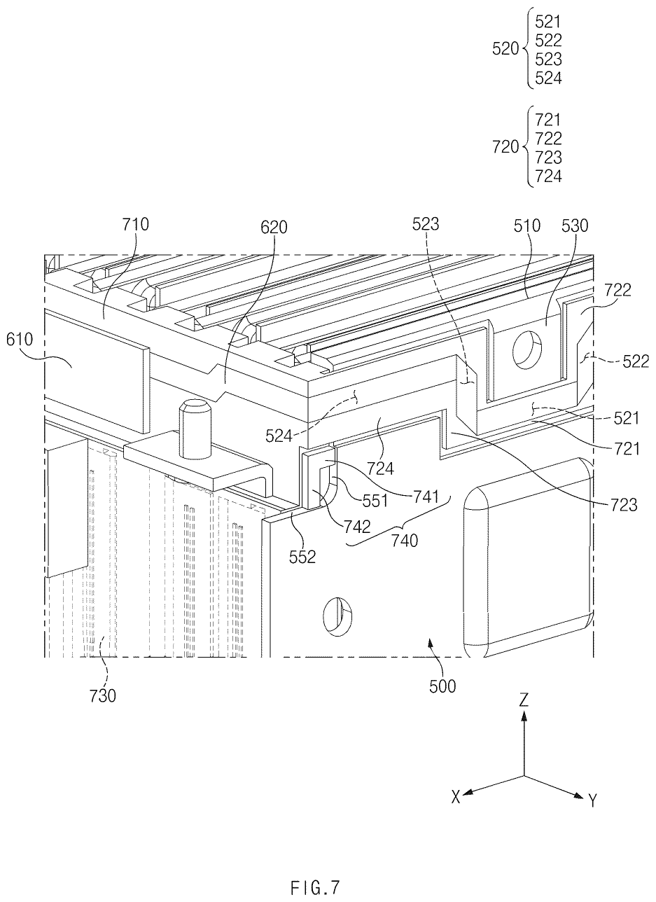

FIG. 3 is a perspective view of a battery assembly. FIG. 4 is an exploded perspective view of a battery assembly. FIG. 5 is a perspective view of a sensing assembly. FIG. 6 is a perspective view of a sensing assembly, when viewed from another angle. FIG. 7 is an enlarged view of portion “A” illustrated in FIG. 3.

Referring to FIGS. 3 to 7, the battery assembly 400 can include a battery cell stack 410 including a plurality of battery cells 420 that extend in a first direction (the “X” direction or an opposite direction to the “X” direction) and are arranged in a second direction (the “Y” direction or an opposite direction to the “Y” direction) that is perpendicular to the first direction.

The battery assembly 400 can include side end plates 500 that are disposed on opposite sides of the battery cell stack 410 in the second direction, and sensing assemblies 600 that are disposed on opposite sides of the battery cell stack 410 in the first direction.

The battery cell stack 410 can include a surface-pressure member 430 that is provided between the battery cells 420 and a cooling plate that contacts the battery cells 420 to cool the battery cells 420. An insulation plate 540 can be attached to the side end plate 500.

A sensing assembly 600 can include a sensing board 610 for measuring a voltage of the battery cells 420, a wire 620 that is electrically connected to the sensing board 610, a busbar 630 that electrically connected to the battery cell 420, and a temperature sensor 640 for measuring a temperature of the battery cells 420.

The sensing assembly 600 can include a sensing support frame 700 that supports the sensing board 610, the wire 620, the busbar 630, and the temperature sensor 640. The sensing support frame 700 can extend along a circumference of the battery cell stack 410, and can cover opposite areas of the battery cell stack 410 in the first direction. That is, the sensing board 610, the wire 620, the busbar 630, and the temperature sensor 640 can be attached to the sensing support frame 700.

The sensing support frame 700 can include a board support part 710, to which the sensing board 610 is attached, and that supports the sensing board 610, a side support part 720, to which the wire 620 and the temperature sensor 640 are attached, and a busbar support part 730 that supports the busbar 630.

A pair of board support parts 710 can be provided, and can be provided on one side (the “X” direction) of the battery cell stack 410 in the first direction and an opposite side (an opposite to the “X” direction) thereof in the first direction, respectively. The pair of board support parts 710 can extend in the second direction from opposite sides of the battery cell stack 410 in the first direction. Insulation covers 440 can be provided on opposite sides of the board support part 710 in the first direction.

A pair of side support parts 720 are provided, and the pair of board support parts 710 can extend in an opposite side in the first direction from, among the pair of board support part 710, the board support part 710 provided on one side (the “X” direction) of the battery cell stack 410 in the first direction to the board support part 710 provided on an opposite side thereof in the first direction (an opposite direction to the “X”direction).

Wires 620 can be mounted on a pair of surfaces of the side support part 720, which face opposite sides in the first direction. The wire 620 can be electrically connected not only to the sensing board 610 but also to the temperature sensor 640, and for the wires 620 to be attached, the side support part 720 can be formed of a material that can be manufactured as an injection-molded product.

The pair of side support parts 720 can be supported by the side end plates 500 provided on opposite sides of the battery cell stack 410 in the second direction, respectively. The side support parts 720 can be disposed in an area on one side (the “Z” direction) in the third direction, on opposite sides of the battery cell stack 410 in the second direction.

The busbar support part 730 can extend from the board support part 710 in an opposite side (an opposite direction to the “Z” direction) in the third direction. One end 731 of the busbar support part 730, which faces an opposite side in the third direction can protrude to one side (the “X” direction) in the first direction so that the busbar 630 is supported between the one end 731 and the board support part 710.

A plurality of busbar support parts 730 can be provided to be spaced apart from each other in the second direction. Tab slots 732 having a shape that is opened to an opposite side in the third direction can be formed between the plurality of busbar support parts 730.

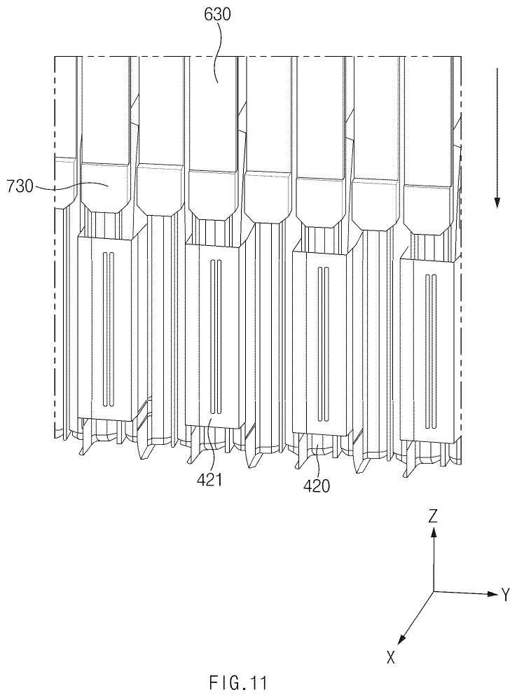

The tab slots 732 can extend in the third direction between the plurality of busbar support parts 730. The tab slots 732 can be spaces, through which electrode tabs 421 (see FIG. 11) of the battery cells 420 pass. The electrode tabs 421 of the battery cells 420 can pass through the tab slots 732 to be electrically connected to the busbar 630.

With the structure, the sensing assembly 600 can be moved from an area on one side (the “Z” direction) of the battery cell stack 410 in the third direction toward the battery cell stack 410, automation can be facilitated in the manufacturing process of the battery assembly 400.

In some implementations, when the sensing assembly 600 is moved toward the battery cell stack 410, toward an opposite side in the third direction (an opposite direction to the “Z” direction), a position of the sensing assembly 600 can be fixed.

In some examples, the sensing support frame 700 can include guide bosses 740 that interfere with the side end plates 500. The guide bosses 740 can protrude outward from the board support part 710 to an outer side in the second direction, and can be seated on the side end plates 500. Here, the outer side in the second direction can be opposite sides in the second direction.

The guide boss 740 can be disposed in an area of the side support part 720 on an opposite side in the third direction. The guide boss 740 can include a first stop area 741 that extends in the first direction, and a second stop area 742 that extends from one end of the first stop area 741 in the first direction to an opposite side (an opposite direction to the “Z”direction) in the third direction.

Both of the first stop area 741 and the second stop area 742 can contact the side end plate 500. In more detail, the side end plate 500 can include a first contact surface 551 that faces one side in the first direction to contact one end of the first stop area 741, and a second contact surface 552 that faces one side in the third direction to contact one end of the second stop area 742.

The second contact surface 552 can extend from the first contact surface 551 toward the one side in the first direction. An area, in which the first contact surface 551 and the second contact surface 552 face each other, can have a shape that is recessed in a direction, in which they are spaced apart from the guide boss 740. In other words, the area, in which the first contact surface 551 and the second contact surface 552 face each other, can be formed to be opened to one side in the first direction and one side in the third direction.

With the structure, even when the sensing assembly 600 is moved from an area of the battery cell stack 410 on one side in the third direction to an opposite side in the third direction, a position of the sensing assembly 600 is guided, and thus, a manufacturing performance of the battery assembly 400 can be improved.

In some examples, when the sensing assembly 600 is mounted on the battery assembly 400, the side support part 720 can be supported by the side end plate 500 so that a position thereof is fixed.

In some implementations, the side end plate 500 can include a seating groove 520 that is formed to be concave on an outside in the second direction to define a space, into which the side support part 720 is inserted.

The seating groove 520 can include a first seating area 521 that extends in the first direction, a second seating area 522 that extends from one end of the first seating area 521 to one side (the “Z” direction) in the third direction, a third seating area 523 that extends from an opposite end of the first seating area 521 to one side (the “Z” direction) in the third direction, and a fourth seating area 524 that extends from the third seating area 523 to one side (the “X” direction) in the first direction. The first to fourth seating areas 521, 522, 523, and 524 can be provided in plural, and the fourth seating area 524 can be provided on an opposite side (an opposite direction to the “X” direction) of the second seating area 522 in the first direction.

The side support part 720 can include a first side area 721 that extends in the first direction to be inserted into the first seating area 521, a second side area 722 that extends from one end of the first side area 721 to one side (the “Z” direction) in the third direction to be inserted into the second seating area 522, a third side area 723 that extending from an opposite end of the first side area 721 to one side (the “Z” direction) in the third direction to be inserted into the third seating area 523, and a fourth side area 724 that extends from the third side area 723 to one side (the “X” direction) in the first direction to be inserted into the fourth seating area 524. The first to fourth side areas 721, 722, 723, and 724 can be provided in plural, and the fourth side area 724 can be provided on an opposite side (an opposite direction to the “X” direction) of the second side area 522 in the first direction.

The side end plate 500 can include a rim cover 510 that is formed on one side (the “Z” direction) of the seating groove 520 in the third direction and supports the side support part 720, and a fixing jig 530 that protrudes from the rim cover 510 in an opposite side (an opposite direction to the “Z”direction) in the third direction.

The rim cover 510 can extend in the first direction and can contact one end of the side support part 720, which faces one side (the “Z” direction) in the third direction. The fixing jig 530 can protrude from the rim cover 510 toward the first seating area 521 between the second seating area 522 and the third seating area 523. The fixing jig 530 can fix the positions of the first to third side areas 721, 722, and 723 to fix the position of the side support part 720.

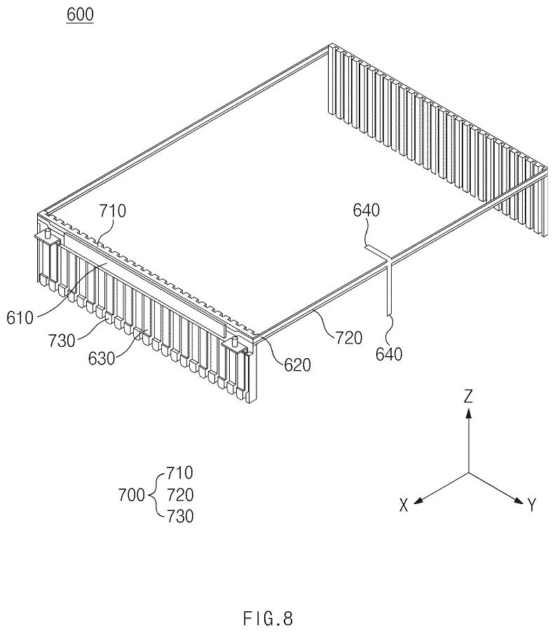

FIG. 8 is a perspective view showing an example of a sensing assembly.

Referring to FIG. 8, unlike the sensing assembly 600 illustrated in FIG. 7, the side support part 720 of FIG. 8 can have a shape that extends in the first direction.

In some implementations, the side end plate 500 can have a shape, in which a seating groove 520 extends in a first direction, unlike the side end plate 500 illustrated in FIG. 7.

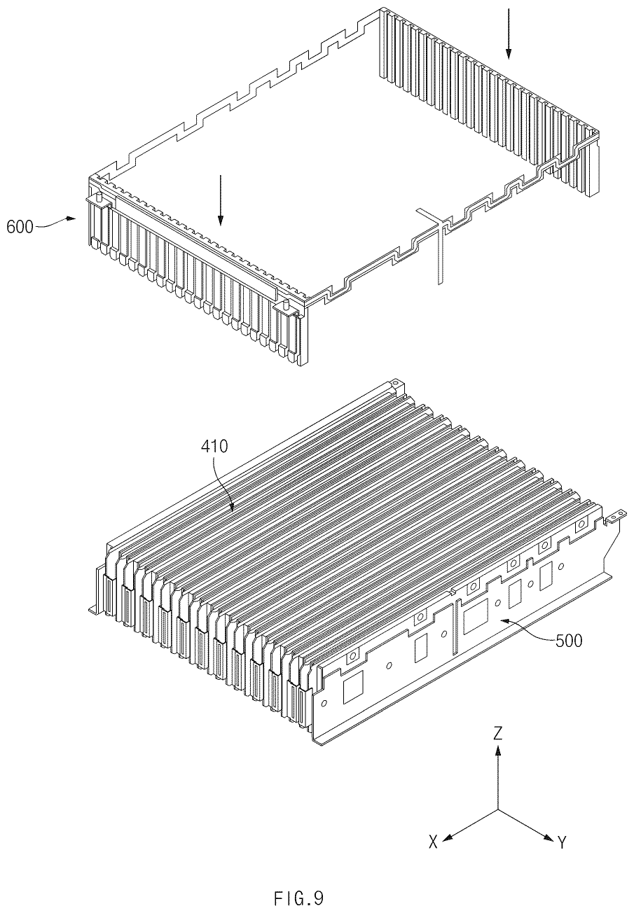

Hereinafter, a method for manufacturing the battery assembly 400 will be described in detail with reference to FIGS. 9 to 14.

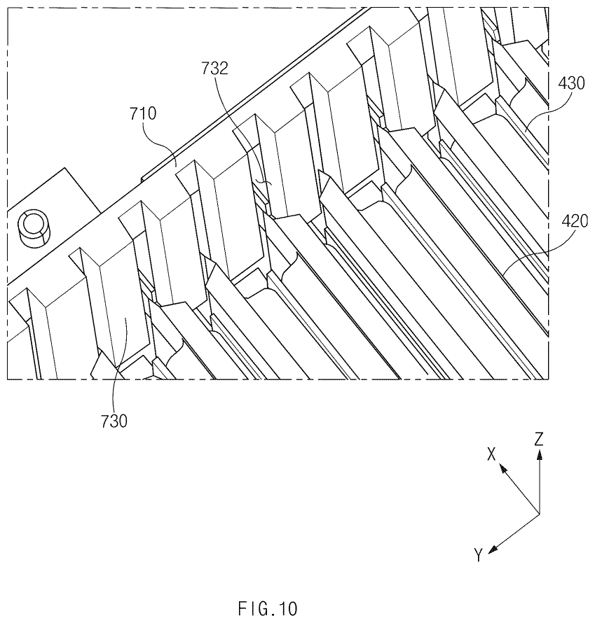

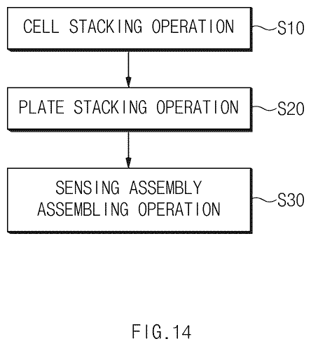

FIG. 9 is a perspective view before a sensing assembly is mounted on a battery cell stack. FIG. 10 is a view, in which a battery cell is inserted into a tab slot of a busbar support part,. FIGS. 11 to 13 are views illustrating a process of moving a sensing assembly to an opposite other side in a third direction and mounting it on a battery cell stack. FIG. 14 is a flowchart illustrating a method for manufacturing a battery assembly.

Referring to FIGS. 9 to 14, a method for manufacturing the battery assembly 400 (see FIG. 3) can include a cell stacking operation S10, a plate stacking operation S20, and a sensing assembly assembling operation S30.

The cell stacking operation S10 can be an operation of stacking the battery cells 420 (see FIG. 4) that extend in the first direction (the “X” direction or an opposite direction to the “X” direction) in the second direction (the “Y” direction or an opposite direction to the “Y” direction) that is perpendicular to the first direction.

When the battery cells 420 are stacked in the cell stacking operation S10, the surface-pressure members 430 and the cooling plates can be stacked together between the battery cells 420.

The plate stacking operation S20 can be an operation of disposing the side end plates 500 on opposite sides of the battery cell 420 in the second direction after the cell stacking operation S10.

The battery cell stack 410 illustrated in FIG. 9 can be in a state, in which a cell stacking operation S10 and a plate stacking operation S20 have been performed.

The sensing assembly assembling operation S30 can be an operation of assembling the sensing assembly 600 and the side end plate 500 by assembling the sensing assembly 600 in the third direction of the battery cell 420 after the plate stacking operation S20.

In the sensing assembly assembling operation S30, the sensing assembly 600 assembled in the side end plate 500 can be in a state, in which the sensing board 610, the wire 620, the busbar 630, and the temperature sensor 640 are attached to the sensing support frame 700.

The sensing assembly 600, to which the sensing board 610, the wire 620, the busbar 630, and the temperature sensor 640 are attached, can be moved toward an opposite side (an opposite direction to the “Z” direction) in the third direction toward a circumferential area of the battery cell stack 410, on an area on one side of the battery cell stack 410 in the third direction.

When the sensing assembly 600 is moved toward an opposite side (an opposite direction to the “Z” direction) in the third direction, the electrode tab 421 of the battery cell 420 can be inserted along a tab slot 732 provided between the busbar support parts 730.

The electrode tabs 421 of the pair of adjacent battery cells 420 can be connected to each other on opposite sides in the first direction. Furthermore, the electrode tabs 421 connected to each other can overlap each other on surfaces thereof, which face opposite sides in the first direction.

Accordingly, for the ease of the manufacturing process, the tab slot 732 can be moved in the third direction so that an area that extends in the first direction is inserted, in addition to an area, in which the electrode tabs 421 are connected to each other. Accordingly, when the tab slot 732 has a shape that extends along the third direction, the manufacturing process can become easy when the sensing assembly 600 is mounted on the battery cell stack 410 as one assembly.

As described above, when the tab slot 732 is moved along the electrode tab 421 to an opposite side (an opposite direction to the “Z” direction) in the third direction, the guide boss 740 can interfere with the side end plate 500 and the side support part 720 can be inserted into the seating groove 520 at the same time as illustrated in FIG. 7.

In some implementations, a separate manufacturing process can be omitted because a configuration of a separate busbar or wire may not be provided in the sensing assembly 600. Furthermore, because the manufacturing of the battery assembly 400 is completed as soon as the sensing assembly 600 is moved in the third direction and is inserted into the side end plate 500, the manufacturing process of the battery assembly 400 accommodated in the battery pack 100 (see FIG. 1) in the form of a CTP can be facilitated, and thus, productivity can be improved.

According to the present technology, the sensing assembly can be mounted on the battery assembly while the wire is attached to the sensing assembly, and thus, the manufacturing process of the sensing assembly and the battery assembly including the same can be automated, whereby productivity can be improved.

In addition, according to the present disclosure, when the sensing assembly is mounted, the position of the sensing assembly is guided by the side end plate, so that the manufacturing process of the battery assembly can be automated, thereby improving productivity.

In addition, various effects directly or indirectly identified through this document can be provided.

The above description is a simple exemplary description of the technical spirits of the present disclosure, and an ordinary person in the art, to which the present disclosure pertains, can make various corrections and modifications without departing from the essential characteristics of the present disclosure.

Therefore, the implementations disclosed in the present disclosure are not for limiting the technical spirits of the present disclosure but for describing them, and the scope of the technical spirits of the present disclosure is not limited by the implementations. The protection scope of the present disclosure should be construed by the following claims, and all the technical spirits in the equivalent range should be construed as being included in the scope of the present disclosure.

What is claimed is:

1. A battery assembly comprising:
a battery cell stack comprising a plurality of battery cells that extend in a first direction and are arranged in a second direction transverse to the first direction;
a side end plate that is disposed at a side of the battery cell stack and faces the plurality of battery cells in the second direction; and
a sensing assembly that covers an area of a side surface of the battery cell stack and faces the plurality of battery cells in the first direction, the sensing assembly comprising a sensing board and a sensing support frame that supports the sensing board,
wherein the sensing support frame comprises:
a board support part that supports the sensing board and extends from the side of the battery cell stack in the second direction,
a side support part that extends from an end of the board support part in the first direction and is supported by the side end plate, and
a guide boss that protrudes from the end of the board support part in the second direction and is disposed on the side end plate.

2. The battery assembly of claim 1, wherein the guide boss comprises:
a first stop area that extends in the first direction; and
a second stop area that extends from the first stop area in a third direction transverse to the first and second directions.

3. The battery assembly of claim 2, wherein the first stop area and the second stop area contact the side end plate.

4. The battery assembly of claim 2, wherein the side end plate comprises:
a first contact surface that faces one side of the first stop area in the first direction and contacts one end of the first stop area; and
a second contact surface that faces one side of the second stop area in the third direction and contacts one end of the second stop area.

5. The battery assembly of claim 4, wherein the side end plate defines a recessed area between the first contact surface and the second contact surface, the recessed area being recessed in a direction away from the guide boss.

6. The battery assembly of claim 1, wherein the sensing assembly further comprises:
a busbar electrically connected to the plurality of battery cells,
wherein the sensing support frame comprises a plurality of busbar support parts that support the busbar and extend from the board support part in a third direction transverse to the first and second directions, and
wherein the plurality of busbar support parts are spaced apart from one another in the second direction to thereby define a plurality of tab slots that extend in the third direction.

7. The battery assembly of claim 6, wherein each of the plurality of busbar support parts comprises a protrusion that is disposed at an end of one of the busbar support parts in the third direction, that protrudes in the first direction, and that supports the busbar.

8. The battery assembly of claim 1, wherein the side end plate defines a seating groove that is recessed in the second direction and receives the side support part.

9. The battery assembly of claim 8, wherein the seating groove comprises:
a first seating area that extends in the first direction;
a second seating area that extends from a first end of the first seating area in a third direction transverse to the first and second directions;
a third seating area that extends from a second end of the first seating area in the third direction; and
a fourth seating area that extends from the third seating area in the first direction.

10. The battery assembly of claim 9, wherein the side support part comprises:
a first side area that extends in the first direction and is inserted into the first seating area;
a second side area that extends from a first end of the first side area in the third direction and is inserted into the second seating area;
a third side area that extends from a second end of the first side area in the third direction and is inserted into the third seating area; and
a fourth side area that extends from the third side area in the first direction and is inserted into the fourth seating area.

11. The battery assembly of claim 9, wherein the side end plate comprises:
a rim cover that is disposed at one side of the first seating area in the third direction and supports the side support part.

12. The battery assembly of claim 11, wherein the side end plate further comprises:
a fixing jig that protrudes from the rim cover toward the first seating area and is disposed between the second seating area and the third seating area, the fixing jig being configured to fix the side support part.

13. The battery assembly of claim 8, wherein the seating groove extends in the first direction, and
wherein the side support part extends in the first direction and is inserted into the seating groove.

14. The battery assembly of claim 1, wherein the sensing assembly further comprises a wire electrically connected to the sensing board, and
wherein the wire is disposed at a surface of the side support part and extends along the side support part in the first direction.

15. A sensing assembly comprising:
a sensing board;
a busbar; and
a sensing support frame that supports the busbar and the sensing board,
wherein the sensing support frame comprises:
a side support part that extends in a first direction,
a board support part that extends from the side support part in a second direction transverse to the first direction, wherein the sensing board is attached to the board support part, and
a plurality of busbar support parts to which the busbar is attached, the plurality of busbar support parts extending from the board support part in a third direction transverse to the first and second directions, and being spaced apart from one another in the second direction.

16. The sensing assembly of claim 15, wherein the sensing support frame further comprises:
a guide boss that protrudes from the board support part to an outer side of the sensing support frame in the second direction, and
wherein the guide boss comprises:
a first stop area that extends in the first direction; and
a second stop area that extends from the first stop area in the third direction.

17. The sensing assembly of claim 15, wherein the side support part comprises:
a first side area that extends in the first direction;
a second side area that extends from a first end of the first side area in the third direction;
a third side area that extends from a second end of the first side area in the third direction; and
a fourth side area that extends from the third side area in the first direction.

18. The sensing assembly of claim 15, wherein each of the plurality of busbar support parts comprises a protrusion that is disposed at an end of one the busbar support parts in the third direction, that protrudes in the first direction, and that supports the busbar.

19. The sensing assembly of claim 15, further comprising a wire electrically connected to the sensing board,
wherein the wire is disposed at a surface of the side support part and extends along the side support part in the first direction.

20. A method for manufacturing a battery assembly, the method comprising:
stacking a plurality of battery cells that extend in a first direction, the plurality of battery cells being stacked in a second direction transverse to the first direction;
disposing a pair of side end plates at opposite sides of the plurality of battery cells, the pair of side end plates facing the plurality of battery cells in the second direction; and
assembling a sensing assembly and the pair of side end plates in a third direction transverse to the first and second directions.
